(19) United States
(12) Patent Application Publication
(10) Pub. No.: US 2026/0372127 A1
(43) Pub. Date: Nov. 19, 2026

(54) COPACKAGED OPTICAL DEVICES AND METHODS OF MANUFACTURE

(71) Applicant: Taiwan Semiconductor Manufacturing Co., Ltd., Hsinchu (TW)

(72) Inventors: Kuan-Lin Ho, Hsinchu (TW); Chun-Chih Chuang, Taichung City (TW); Jung Wei Cheng, Hsinchu (TW); Hsien-Pin Hu, Zhubei City (TW); Shang-Yun Hou, Jubei City (TW)

(21) Appl. No.: 19/750,025

(22) Filed: Jul. 22, 2026

Related U.S. Application Data
(63) Continuation of application No. 18/927,486, filed on Oct. 25, 2024.

(51) Int. Cl. H10W 70/60; H10W 90/00; H10W 95/00; H10W 74/10; H10W 74/15

(52) U.S. Cl. CPC H10W 70/611; H10W 90/00; H10W 90/401; H10W 95/00; H10W 74/111; H10W 74/15; H10W 90/724; H10W 90/734

(57) ABSTRACT

A method that includes bonding at least one of a redistribution layer interposer substrate onto a package substrate, bonding packaging components and memory components to an upper surface of the redistribution layer interposer substrate; and bonding a photonics chip to the upper surface of the redistribution layer interposer substrate.

### CROSS-REFERENCE TO RELATED APPLICATIONS

This application is a continuation of U.S. Application No. 18/927,486, filed on Oct. 25, 2024, which application is hereby incorporated herein by reference.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an optical device integrated with an interposer, in accordance with some embodiments.

FIGS. 2-6 illustrate the views of intermediate stages in the formation of optical devices using a chip on wafer on substrate (CoWoS) architecture, in accordance with some embodiments.

FIGS. 7A-7D illustrate views of bonding a photonics chip to a redistribution layer (RDL) substrate using solder bonding methods, in accordance with some embodiments.

FIGS. 8A-8C illustrate views of bonding a photonics chip to a redistribution layer (RDL) substrate by forming solder bumps through openings in the molding from underfill/encapsulation processes, in accordance with some embodiments.

FIGS. 9A-9C illustrate views of bonding a photonics chip to a redistribution layer (RDL) substate by forming solder bumps on a through insulator via (TIV), in accordance with some embodiments.

FIGS. 10A-10B illustrate views of bonding a photonics chip to a redistribution layer (RDL) substrate using solder bonding methods, in which molding has been etched to provide hollow trim, in accordance with some embodiments.

FIGS. 11A-11B illustrate views of bonding a photonics chip to a redistribution layer (RDL) substate by forming solder bumps through openings in the molding from underfill/overmolding processes, in which the molding has been etched to provide hollow trim, in accordance with some embodiments.

FIGS. 12A-12B illustrate views of bonding a photonics chip to a redistribution layer (RDL) substate by forming solder bumps on a through insulator via (TIV), in which molding has been etched to provide hollow trim, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which an optical interposer is present on an interposer that also includes compact photonic engine chips in order to provide optical interconnections between optical devices. In some embodiments, the photonic engine chips can combine an electronic integrated circuit (EIC) with a photonic integrated circuit (PIC) using system on integrated chip (SoIC) packaging technology. SoIC includes 3D inter-chip (3D IC) stacking technologies for integration of chiplets partitioned from System on Chip (SoC).

The embodiments presented herein are intended to be illustrative and are not intended to limit the embodiments to the precise descriptions as discussed. Rather, the embodiments discussed may be incorporated into a wide variety of implementations, such as silicon photonics in general, or 3-D ICs with photonic applications, and all such implementations are fully intended to be included within the scope of the embodiments.

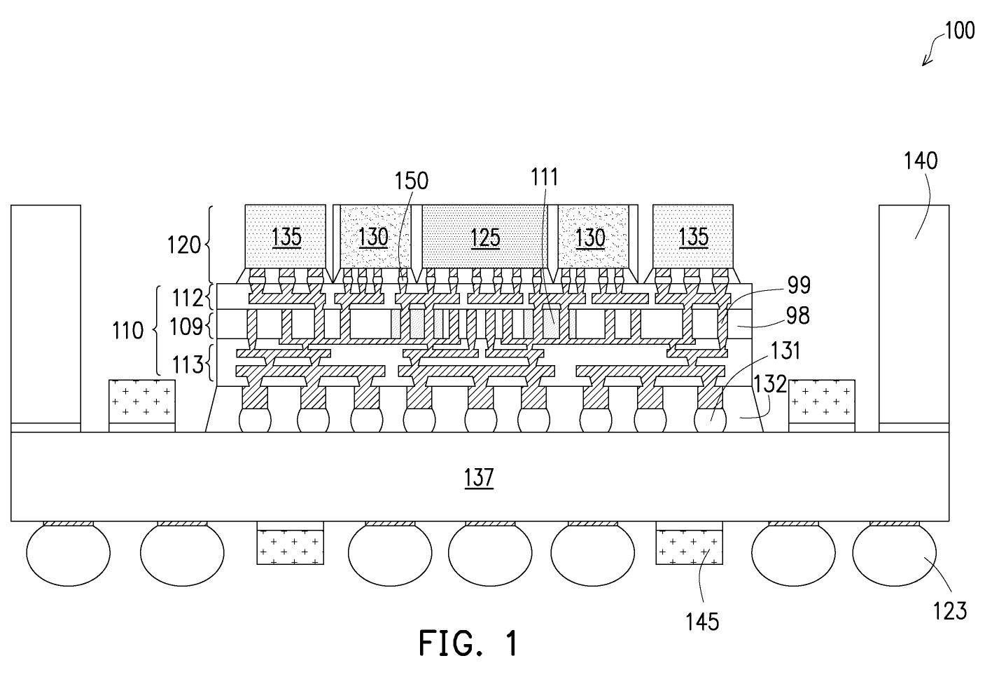

With reference now to FIG. 1, there is illustrated a Chip-on-Wafer-on-Substrate (CoWoS) substrate 100 architecture including a redistribution layer (RDL) interposer substrate 110. In one embodiment, the CoWoS substrate architecture may be CoWoS-R or CoWoS-L substrate architecture. CoWoS-R is a type of packaging that can employ Integrated Fan Out (InFO) wafer level packaging featuring at least one redistribution layer (RDL) and through insulator via (TIV) (also referred to through InFO via) for providing interconnects between chiplets. For example, in FIG. 1, at least one redistribution layer (RDL) is present in a redistribution layer (RDL) interposer substrate 110. CoWoS-L include local silicon interconnect (LSI) chip 111 for die-to-die interconnect and redistribution layers (RDLs) for power and signal deliver.

In one embodiment, the redistribution layer (RDL) interposer substrate 110 can include local silicon interconnects (LSI) chips 111, a front side redistribution layer (FSRDL) 112, and a back side redistribution layer (BSRDL) 113, which may collectively be referred to as the circuitry of the redistribution layer (RDL) interposer substrate 110. The circuitry of the redistribution layer (RDL) interposer substrate 110 can provide for electrical communication top with the top dies components 120 that are connected to the top surface of the redistribution layer (RDL) interposer substrate 110 to the substrate 137 (e.g., printed circuit board (PCB) substrate). The circuitry of the redistribution layer (RDL) interposer substrate 110 can also provide for interconnectivity of the chips of the top die components 120. In some embodiments, the redistribution layer (RDL) interposer substrate 110 is a molding-based interposer with wide pitch of redistribution layers (RDL) on both front-side and back-side and TIV (Through Interposer Via) for signal and power delivery provides low loss of high frequency signal in high-speed transmission.

The redistribution layer (RDL) interposer substrate 110 can be connected to the substrate 137 (e.g., printed circuit board (PCB) substrate) through solder bonds 131, such as C4 solder bonds. The opposite side of the substrate 137 (e.g., printed circuit board (PCB) substrate) may also include solder bumps 123, e.g., ball grid array (BGA) solder. In some embodiments, the substrate 137 may also include a ring structure 140 and one or more surface mount device (SMD) chips 145 directed connected thereto.

In one embodiment, the top die components 120 include package components 125, memory components 130, and at least one photonics chip 135, which may be a compact photonics engine chip. For example, the package components 125 may include a device die, a package with a device die(s) packaged therein, a System-on-Chip (SoC) or System-on-Integrated Circuit (SoIC) die including a plurality of integrated circuits (or device dies) integrated as a system, or the like. The device dies in package components 125 may be or may comprise logic dies, memory dies, input-output dies, Integrated Passive Devices (IPDs), or the like, or combinations thereof. For example, the logic device dies in package components may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in package components 125 may include Static Random-Access Memory (SRAM) dies, Dynamic Random-Access Memory (DRAM) dies, or the like. The device dies in package components 125 may include semiconductor substrates and interconnect structures.

In some embodiments, the memory components 130 may include a memory stack, such as a High Bandwidth Memory (HBM) stack. In some other embodiments, the memory components 130 may include memory dies forming a die stack, and an encapsulate (such as a molding compound) regions encapsulating memory dies therein.

In some embodiments, the package components 125 and the memory components 130 may be bonded to the underlying redistribution layer (RDL) interposer substrate 110, for example, through bonds 150. In accordance with some embodiments, the bonding is through a Chip-on-Wafer (CoW) bonding process, wherein the package components 125 and the memory components 130, which are discrete chips/packages, are bonded to the redistribution layer (RDL) interposer substrate 110.

In some embodiments, the top die components 120 also include a photonics chip 135, which may be a compact photonics engine chip. In some embodiments, the compact photonics engine chips can combine an electronic integrated circuit (EIC) with a photonic integrated circuit (PIC) using system on integrated chip (SoIC) packaging technology, such as dielectric-to-dielectric and metal-to-metal bonding processes. Photonic integrated circuits (PIC) are designed to harness the unique properties of light, offering advantages such as high bandwidth, low power consumption, and faster data transfer speeds compared to their electronic counterparts. These circuits often include components, such as waveguides, couplers, lasers, light emitting diodes (or other sources of coherent light), modulators, detectors, and other optical elements, such as mirrors and reflectors. However, any suitable components may be utilized.

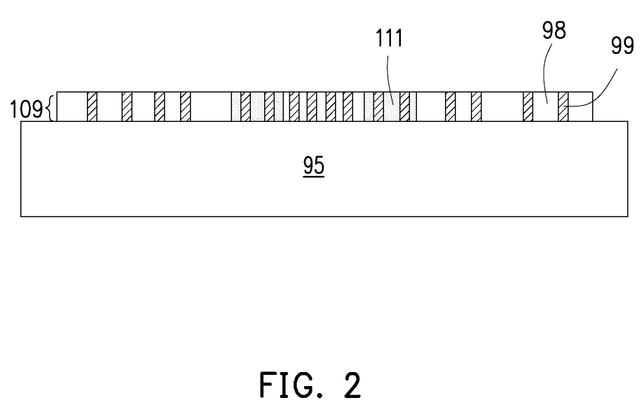

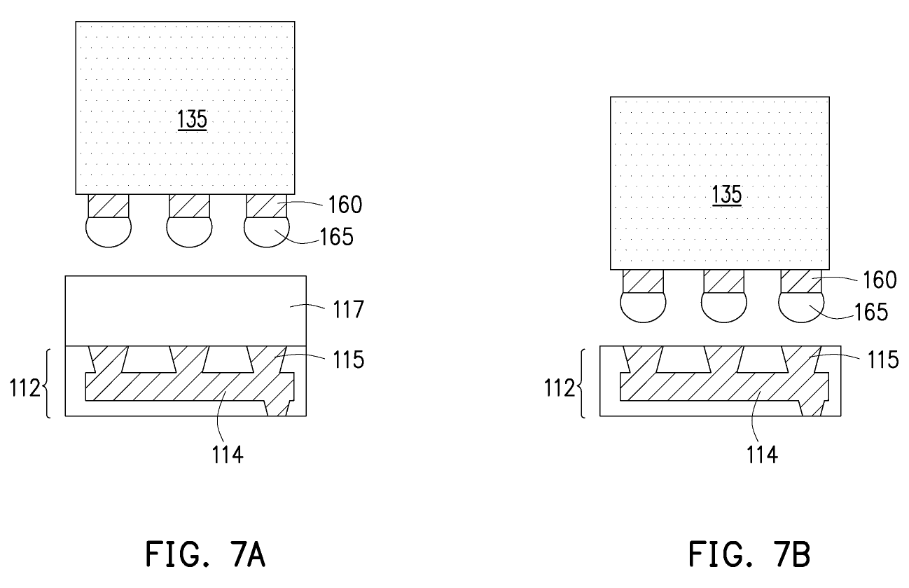

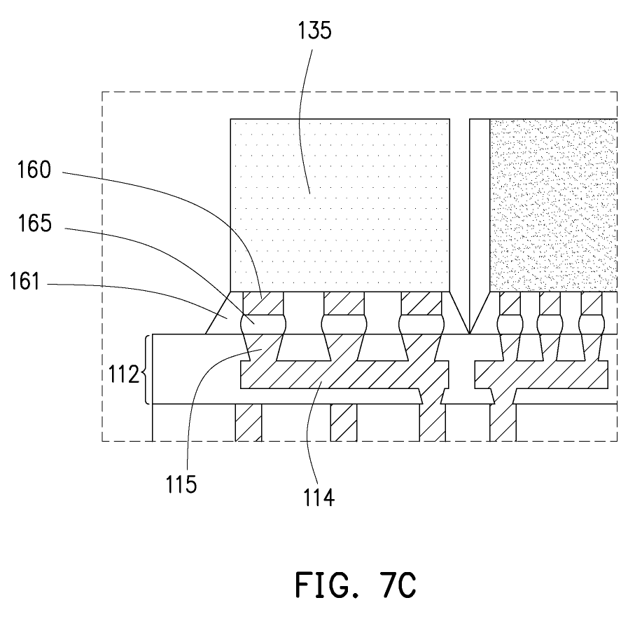

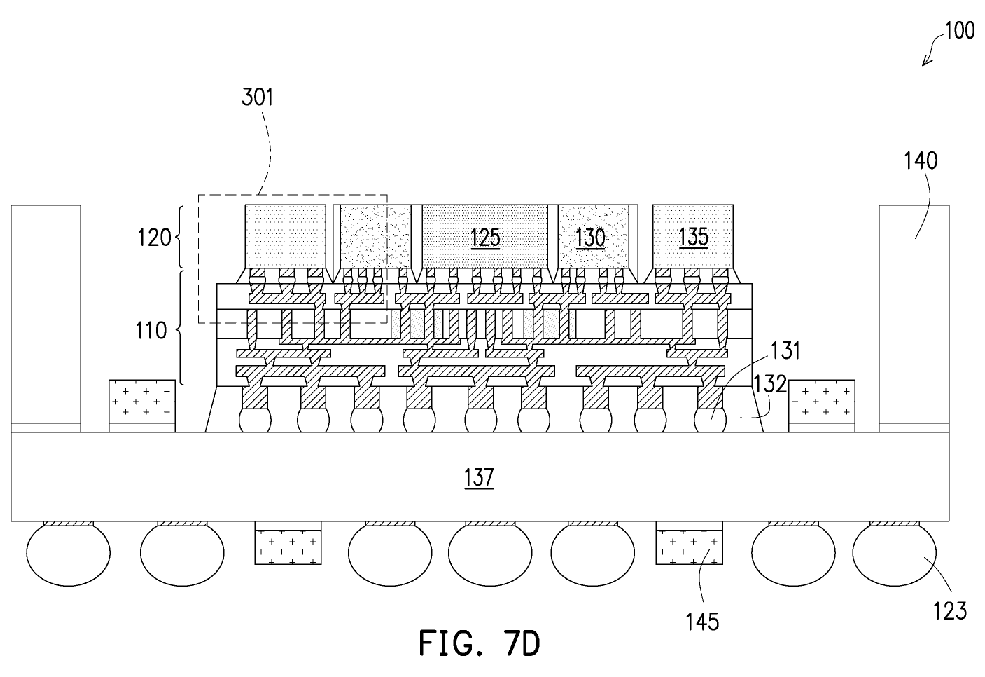

The Chip-on-Wafer-on-Substrate (CoWoS) architecture including the redistribution layer (RDL) interposer substrate 110 can be formed using the methods described with reference to FIGS. 2-6. The engagement of the photonics chip 135 to the redistribution layer (RDL) interposer substrate 110 can occur after the top die (TD) loop, and includes trimming the molding 117 of the underfill/overmold processing that accompanies solder bonding of the package components 125 and the memory components 130 to the redistribution layer (RDL) interposer substrate 110. Some embodiments for the methods for engaging the photonics chip 135, e.g., compact photonics engine chip, to the redistribution layer (RDL) interposer substrate 110, is described with reference to FIGS. 7A-12B.

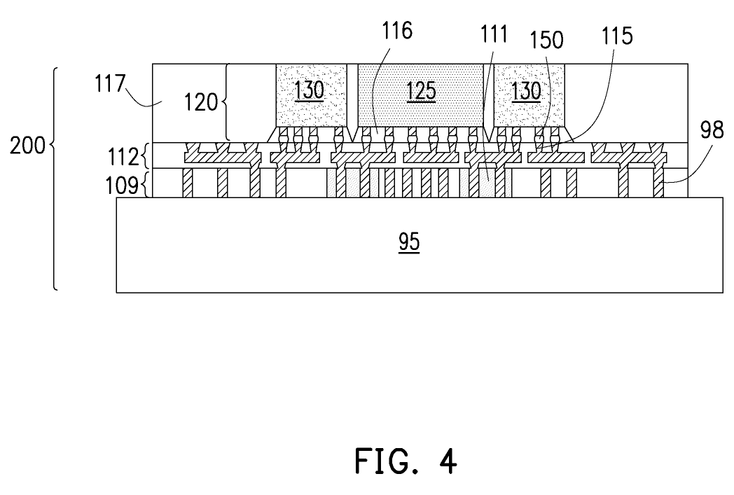

FIG. 2 is a side cross sectional view of forming a local silicon interconnect (LSI) layer 109. The local silicon interconnect (LSI) layer 109 includes local silicon interconnect (LSI) chips 111 are formed in an insulating layer 98 that includes metal lines/interconnects 99 formed therein. In some embodiments, the metal lines/interconnects 99 may be through insulator vias (TIV). In the embodiment depicted in FIG. 2, the local silicon interconnect (LSI) chips 111 include two LSI dies. In some embodiments, the methods and structures described herein integrate a local silicon interconnect (LSI) chips 111, e.g., LSI dies, for communication between two components of the later formed top die components 120, as depicted in FIG. 4.

Referring to FIG. 2, the local silicon interconnect (LSI) chips 111 acts as an intermediary silicon die, connecting the top die components 120, e.g., the later connected package components 125, memory components 130 and/or photonics chip 135. In some embodiments, the local silicon interconnect (LSI) chips 111 may be integrated into the local silicon interconnect (LSI) layer 109 that includes metal lines/interconnects 99 and insulating layers 98 that are arranged to provide redistributing I/O connections. Both the local silicon interconnect (LSI) chips 111 and the metal lines/interconnects 99 may include vertical vias for the metal lines/interconnects. The vertical vias can enable signal passage between layers, vital for proper signal routing.

In an embodiment, the vias (e.g., metal lines/interconnects 99) of the local silicon interconnect (LSI) layer 109 are first formed. Thereafter, the local silicon interconnect (LSI) chips 111 are placed, and then both the vias and the local silicon interconnect (LSI) chips 111 are encapsulated within the insulating layer 98. The structure including local silicon interconnect (LSI) chips 111 encapsulated in the insulating layer 98 may then be planarized. The first carrier wafer 95 may be placed underlying the local silicon interconnect (LSI) layer 109 including the local silicon interconnect (LSI) chips 111 to provide mechanical support. In some embodiments, a release film, which may be a Light-to-Heat Conversion (LTHC) layer, may adhere the local silicon interconnect (LSI) layer 109 including the local silicon interconnect (LSI) chips 111 to the first carrier wafer 95. The first carrier wafer 95 may be composed of a semiconductor material, such as silicon (Si), or glass.

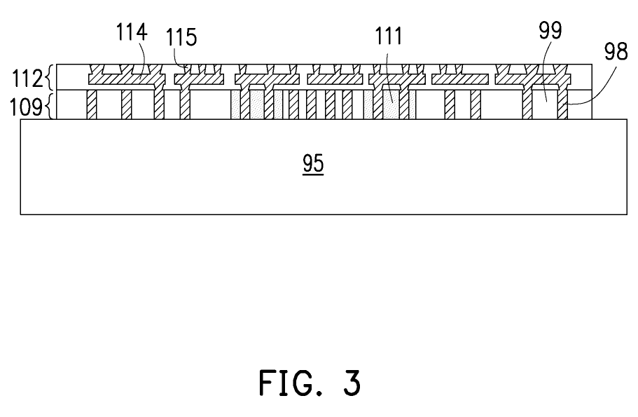

FIG. 3 is a side cross-sectional view illustrating forming a front side redistribution layer (FSRDL) 112 on the local silicon interconnect (LSI) layer 109 including the local silicon interconnect (LSI) chips 111. The front side redistribution layer (FSRDL) 112 includes a metal interconnect layer 114 that electrically connects different top die components 120, e.g., the later connected package components 125, memory components 130 and/or photonics chip 135, for the purposes of signal and/or power routings. The front side redistribution layer (FSRDL) 112 redistributes the electrical connections, allowing bond pads on the chip to connect to package leads or balls. The bond pads for the top die components 120 may be formed on interconnect vias 115. The metal interconnect layer 114 and the interconnect vias 115 may be present in one or more layers of insulating material.

The front side redistribution layer (FSRDL) 112 that includes the metal interconnect layer 114 and the interconnect vias 115 may be formed using deposition processes, such as chemical vapor deposition, and/or spin on deposition for forming the insulating materials. Openings and trenches for the metal lines and/or traces can be formed using photolithography and etch processes. Further, the metal material, such as copper and/or aluminum, for the metal lines and/or traces may be formed using deposition processes, such as sputtering, and/or plating. In some embodiments, the upper surface of the front side redistribution layer (FSRDL) 112 may be planarized using a planarization process, such as chemical mechanical planarization (CMP).

FIG. 4 is a side cross-sectional view illustrating bonding of the top die components 120, e.g., the package components 125, and the memory components 130, to the front side redistribution layer (FSRDL) 112. The top die components 120 may be bonded to contacts on the front side redistribution layer (FRDSL) 112 using a solder bonding/flip chip type process. The bonds 150 provide for connection between the contacts pads of the interconnect vias 115 and the contact pads of the top die components 120. In some embodiments, the solder bonding method may include micro-bumps, which can have a bump size of 25 microns or less. In some embodiments, the micro-bumps may be provided by copper micro-bumps. In some embodiments, the micro-bumps may also be composed of lead free materials, such as SnAg, SnCu, SnAgCu. In some other cases, the micro-bumps may be PbAg. The bonds 150 may be formed using indirect bonding, mass reflow, thermal compression bonding, direct bonding, Cu-to-Cu diffusion bonding, insert bump bonding and combinations thereof. It is noted that the above micro-bump methods are provided for illustrative purposes only. Other examples of solder application methods can include printing of solder paste, engraved mask stump, photosensitive organic mask and squeegee, electroplating of solder, evaporation, needle dispensing, solder paste printing, plated solder bumps, plated copper pillars with micro-bumps and combinations thereof.

After the application of solder to the contacts for the top die components 120, the solder may then be contacted to the contacts on the contact pads of the interconnect vias 115 under elevated temperature and pressure to effectuate bonding. Following bonding, an underfill 116 may be applied. The underfill 116 may be a thermoset epoxy or polymer that's applied to the bonds 150 to protect them and strengthen solder joints.

In some embodiments, the underfill 116 can be applied after the solder bump has gone through a reflow oven and can be dispensed using an automated syringe. In some embodiments, the syringe is positioned to introduce the underfill 116 into the structure including at least the top die components 120, e.g., the package components 125, and the memory components 130, bonded to the front side redistribution layer (FSRDL) 112. The underfill 116 can then flow underneath the top die components 120, e.g., the package components 125, and the memory components 130, using capillary action.

In some embodiments, after the application of the underfill 116, the structure including at least the under filled top die components 120, e.g., the package components 125, and the memory components 130, bonded to the front side redistribution layer (FSRDL) 112 is placed in a mold. Following positioning within the mold, the encapsulant is then applied filling the mold. In some embodiments, a portion of the encapsulant material may extend from beneath the top die components 120, e.g., the package components 125, and the memory components 130, onto the exposed upper surface of the front side redistribution layer (FSRDL) 112. The portion of the underfill and/or encapsulant extends from beneath the top components 120 is hereafter referred to as molding 117.

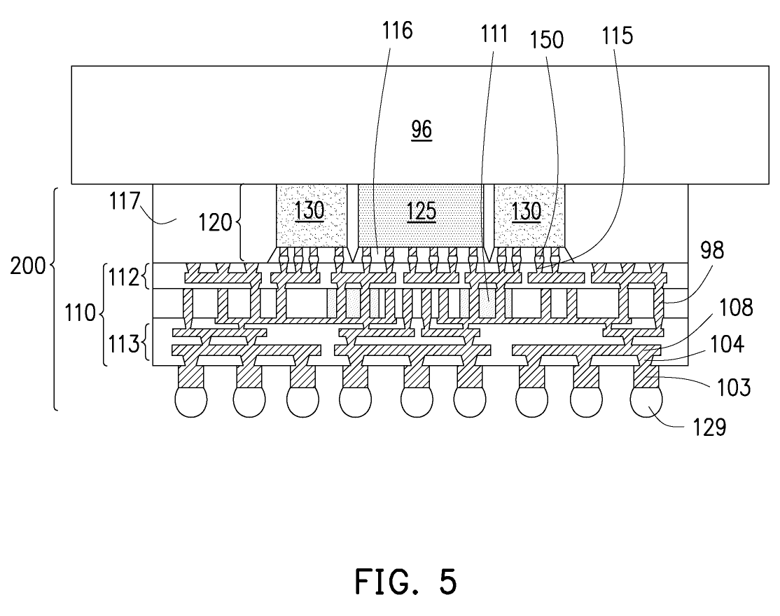

FIG. 5 is a side-cross sectional view illustrating bonding the structure including the top die components 120 to a second carrier wafer 96. In some embodiments, a release film, which may be a Light-to-Heat Conversion (LTHC) layer, may adhere the top die components 120, e.g., the package components 125, and the memory components 130, to second carrier wafer 96. The second carrier wafer 96 may be composed of a semiconductor material, such as silicon (Si), or glass. After the second carrier wafer 96 is bonded to the top die components 120, e.g., the package components 125, and the memory components 130, the first carrier wafer 95 may be removed. For example, the first carrier wafer 95 may be de-bonded, for example, by projecting a laser beam on the release film, thus decomposing the release film. After removing the first carrier wafer 95, the backside surface of the local silicon interconnect (LSI) layer 109 including the local silicon interconnect (LSI) chips 111 is exposed.

FIG. 5 further depicts forming a back side redistribution layer (BSRDL) 113 on the back side surface of local silicon interconnect (LSI) layer 109. The back side redistribution layer (BSRDL) 113 includes a metal interconnect layer 108 that may be present in one or more layers of insulating material. The back side redistribution layer (BSRDL) 113 also includes interconnect vias 104 that extend to contacts 103 that are present on the backside surface of the back side redistribution layer (BSRDL) 113.

The back side redistribution layer (BSRDL) 113 that includes the metal interconnect layers 108 and the interconnect vias 104 may be formed using deposition processes, such as chemical vapor deposition, and/or spin on deposition for forming the insulating materials. Openings and trenches for the metal lines and/or traces can be formed using photolithography and etch processes. Further, the metal material, such as copper and/or aluminum, for the metal lines and/or traces may be formed using deposition processes, such as sputtering, and/or plating. In some embodiments, the backside surface of the back side redistribution layer (BSRDL) 113 may be planarized using a planarization process, such as chemical mechanical planarization (CMP).

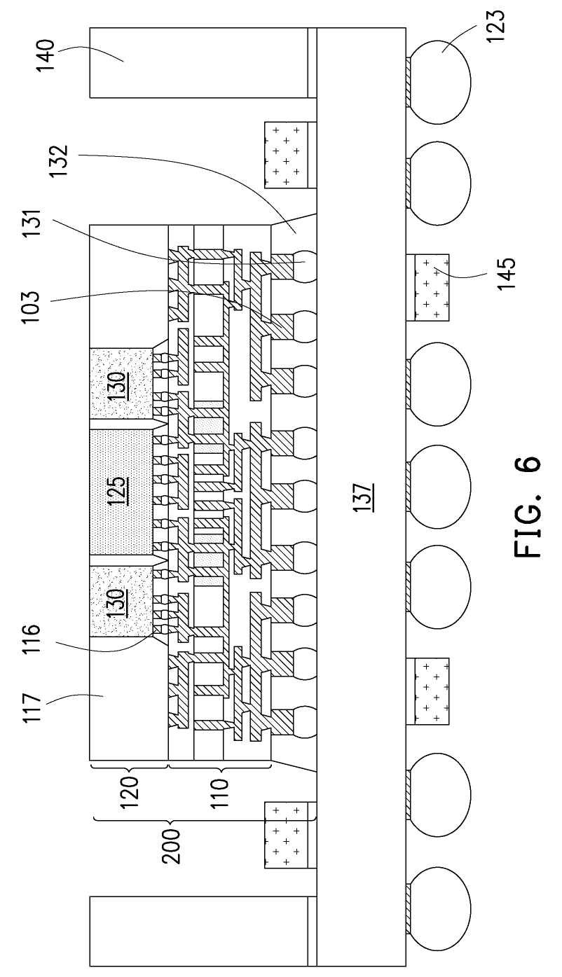

FIG. 5 further illustrates forming solder bumps 129 on the contacts 103. In some embodiments, the solder bumps 129 may be C4 bumps. C4 (collapse chip connection) bumps, can be used to bond the chip 200 to a chip carrier, e.g., substrate 137, as depicted in FIG. 6. The term "solder", as used herein, refers to any metal or metallic compound or alloy that is melted and then allowed to cool in order to join two or more metallic surfaces together. Generally speaking, solders have melting temperatures in the range of 150° C. to 250° C. Solder bumps may be small spheres of solder (solder balls) that are bonded to contact areas, interconnect lines or pads of semiconductor devices. In some embodiments, the solder bumps can be made from lead-free solder mixtures or lead tin solder.

In some embodiments, the solder bump process for forming the solder bonds can include an in-situ sputter clean to remove oxides or photoresist prior to metal deposition on the contacts 103. The cleaning also serves to roughen the surface of the contacts 103 (also referred to as bond pad) in order to promote better adhesion of the under ball metallization (UBM). A metal mask can be used to pattern the structure for UBM and bump deposition. In one embodiments, a sequential evaporation of a chromium layer, a phased chromium/copper layer, a copper layer and an Au layer are deposited to form a thin film under ball metallurgy (UBM) on the contact 103. In one example, Lead-tin solder is then evaporated on top of the UBM to form a thick layer. The height of the bump is determined by the volume of the evaporated material that is deposited. This is also a function of the distance between the metal mask and the wafer, as well as the size of the mask opening. The deposited solder is conical in shape, due to the way that the solder is formed in the openings of the solder mask. The solder can be reflowed to form a sphere.

In some embodiments, the flip-chip processes for bonding the chip 200 to the substrate 137 involved the formation of C4 (controlled-collapse chip connection) bumps, which range from 200μm to 75μm in diameter. It is noted that the aforementioned C4 solder method is provided for illustrative purposes only. Other solder methods may be equally applicable, such as printed solder paste bumps, and electroplated solder bumps.

FIG. 6 illustrates a side cross-sectional view depicting bonding surface mount device (SMD) chips 145 to the substrate 137 (e.g., printed circuit board (PCB) substrate). In some embodiments, the surface mount devices (SMD) chips 145 may be passive devices, such as resistors and capacitors. In some embodiments, the surface mount device (SMD) chips 145 can be bonded to the substrate 137 (e.g., printed circuit board (PCB) substrate) through solder bonds, such as C4 solder bump bonds.

FIG. 6 also illustrates bonding a ring structure 140 to the substrate 137. The ring structure 140 may be provided for thermal cooling of the device.

FIG. 6 further illustrates forming a ball grid array (BGA) on the backside of the substrate 137. In some embodiments, the ball grid array (BGA) may include solder bumps 123. In some embodiments, the solder bumps 123 for the ball grid array may be C4 solder bump bonds.

FIG. 6 further illustrates removing the second carrier wafer 96. For example, the second carrier wafer 96 may be de-bonded, for example, by projecting a laser beam on release film, thus decomposing release film. After removing the second carrier wafer 96, the upper surface of the top die components 120 is exposed, e.g., the top surface of the package components 125 and the memory components 130 is exposed.

FIGS. 2-6 illustrate the views of intermediate stages in the formation of optical devices using a chip on wafer on substrate (CoWoS) architecture, which can be processed to accept photonics chips 135 along with the top die components 120. The methods and structures of the present disclosure bond the photonics chip 135, e.g., a compact photonics engine chip, to the upper surface of the redistribution layer (RDL) interposer substrate 110. In some embodiments, by bonding the photonics chip 135, e.g., compact photonics engine chip, to the upper surface of the redistribution layer (RDL) interposer substrate 110, the electrical pathway between the photonics chip 135, e.g., compact photonics engine chip, and the package components 125, e.g., System-on-Chip (SoC) and/or System-on-Integrated Circuit (SoIC) chips, is minimized, which can increase device performance. Additionally, mounting the photonics chip 135, e.g., compact photonics engine chip, to the upper surface of the redistribution layer (RDL) interposer substrate 110, as opposed to other locations, such as mounting to the substrate 137, can also advantageously reduce risk to the photonics chip 135, e.g., compact photonics engine chip, which could result from warpage. Further, by positioning the photonics chip 135, e.g., compact photonics engine chip, on the upper surface of the redistribution layer (RDL) interposer substrate 110, the methods and structures described herein allow for adjustability of the height of the upper surface of the photonics chip 135 so that it may be approximately equal to the height of the ring structure 140, which can aid in the attachment of a fiber array unit (FAU) to the photonics chip 135. The methods and structures described herein can provide that the heights of the photonics chip 135 and the ring structure 140 be coplanar independently of the other top components 120, which can be higher or lower than the photonics chip 135.

Some embodiments for methods for engaging the photonics chip 135, e.g., compact photonic engine chip, to the redistribution layer (RDL) interposer substrate 110, are described with reference to FIGS. 7A-12B. In each of the following process flows, bonding the photonics chip 135 may begin with removing at least a portion of the molding 117 that is covering the portions of the redistribution layer (RDL) interposer substrate 110. For example, portions of the molding 117 are removed from the redistribution layer (RDL) interposer substrate 110 to expose the electrical connections of the interconnect metal within the redistribution layer (RDL) interposer substrate 110 that the photonics chip 135, e.g., compact photonic engine chip, will be bonded to. The molding 117 is removed from the portion of the redistribution layer (RDL) interposer substrate 110 that is adjacent to the portion of the redistribution layer (RDL) interposer substrate 110 that the memory components 130, e.g., high bandwidth memory (HBM) module, are bonded to. In some embodiments described herein, there can be a memory component 130, e.g., high bandwidth memory (HBM) module, on each side of the package component 125, e.g., System-on-Chip (SoC) and/or System-on-Integrated Circuit (SoIC) chips. In accordance with these embodiments, a photonics chip 135, e.g., compact photonics engine chip, may then be bonded adjacent to each of the memory components 130.

FIGS. 7A-7D illustrate views of bonding the photonics chip 135, e.g., compact photonics engine chip, to the redistribution layer (RDL) interposer substrate 110 using solder bonding methods, in accordance with some embodiments. FIG. 7A illustrates applying a solder ball 165, e.g., micro-ball, to the contacts 160 of the photonics chip 135, e.g., compact photonics engine chip, before the photonics chip 135 is bonded to the interconnect vias 115 of the front side redistribution layer (FSRDL) 112.

In some embodiments, the solder balls 165 may include micro-bumps, which can have a bump size of 25 microns or less. In some embodiments, the micro-bumps may be provided by copper micro-bumps. In some embodiments, the micro-bumps may also be composed of lead free materials, such as SnAg, SnCu, SnAgCu or combinations thereof. In some other cases, the micro-bumps may be PbAg.

It is noted that the above micro-bumps are provided for illustrative purposes only. Other examples of bonds and bonding methods can include printing of solder paste, engraved mask stump, photosensitive organic mask and squeegee, electroplating of solder, evaporation, needle dispensing, solder paste printing, plated solder bumps, plated copper pillars with micro-bumps and combinations thereof. In FIG. 7A, the upper surfaces of the interconnect vias 115 are covered with molding 117.

FIG. 7B illustrates removing the molding 117 to expose the upper surfaces of the interconnect vias 115. In some embodiments, the portions of the molding 117 that extend over the upper surfaces of the front side redistribution layer (FSRDL) 112 are adjacent to the top die components 120. In some examples, the portions of the molding 117 overlying the interconnect vias 115 that the photonics chip 135 is to be bonded to may be removed using an etch process. In some embodiments, an etch mask, such as a photoresist mask, may be formed exposing the portions of the device including the molding 117 that is to be removed, and protecting the other portions of the device so that they are not damaged by the etch process for removing the molding 117.

In some embodiments, a photoresist mask (not shown) may be formed by blanket depositing a photoresist material layer, followed by patterning and development of the photoresist material layer to provide the openings through which the etchant can remove the portions of the molding 117 that are overlying the interconnect vias 115 that the photonics chip 135, e.g., compact photonic engine chip, is to be bonded to. The photoresist material layer may be patterned using photolithography. The etch process for removing the exposed portion of the molding 117 may be an anisotropic etch process. For example, the anisotropic etch process for removing the molding 117 may include reactive ion etching (RIE). In some embodiments, the etch process for removing the molding 117 may remove the material of the molding selectively to the insulating material of the front side redistribution layer (FSRDL) 112, as well as being selective to the interconnect vias 115. In some embodiments, if insulating material of the front side redistribution layer (FSRDL) 112 is present over the interconnect vias 115 it may also be removed using an etching process.

It is noted that etching is not the only method that may be employed to remove the molding 117. Physical removal processes such as sawing may also be used to remove the molding 117 in order to expose the upper surfaces of the interconnect vias 115 in the front side redistribution layer (FSRDL) 112.

Referring to FIG. 7C, after removing the molding 117 the application of solder to the contacts 160 for the photonics chip 135, e.g., compact photonics engine, the solder may then be contacted to the interconnect vias 115 under elevated temperature and pressure to effectuate bonding. FIG. 7C is an enlarged view of the window identified by reference number 301 in FIG. 7D. Following bonding, an underfill 161 may be applied. The underfill 161 may be a thermoset epoxy or polymer that's applied to solder balls 165 to protect them and strengthen solder joints. In some embodiments, the underfill 161 can be applied after the solder bump has gone through a reflow oven and can be dispensed using an automated syringe. The underfill 161 flows underneath the photonics chip 135, e.g., compact photonics engine chip, using capillary action and can be heated to cure.

FIG. 7D is a side cross sectional view depicting the engagement, e.g., bonding, of the photonics chip 135, e.g., compact photonics engine chip, to the redistribution layer (RDL) interposer substrate 110. As illustrated in FIG. 7D, the upper surface of the photonics chip 135, e.g., compact photonics engine chip, is coplanar with an upper surface of the ring structure 140. The upper surface of the photonics chip 135, e.g., compact photonics engine chip, is coplanar with an upper surface of top die components 120, e.g., an upper surface of the package component 125, e.g., System-on-Chip (SoC) and/or System-on-Integrated Circuit (SoIC) chips, and/or is coplanar with the upper surface of the memory components 130, e.g., high bandwidth memory (HBM) module. By increasing the height of the upper surface of the photonics chip, e.g., compact photonics engine chip, to be coplanar with the upper surfaces of the ring structure 140, the methods and structures provide a more accessible location for mounting a fiber array unit (FAU) to the photonics chip 135, e.g., compact photonics engine chip.

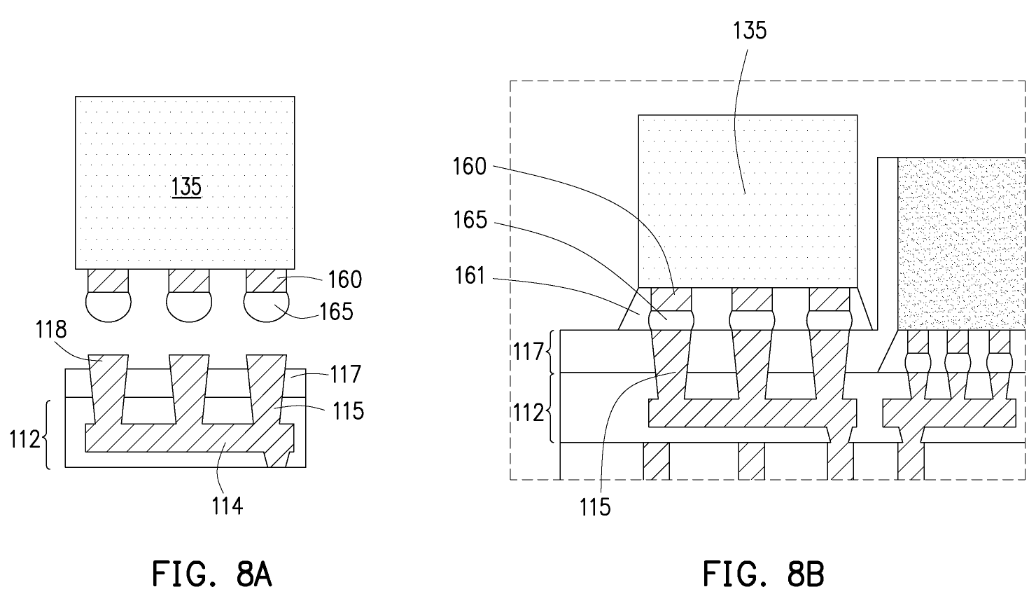

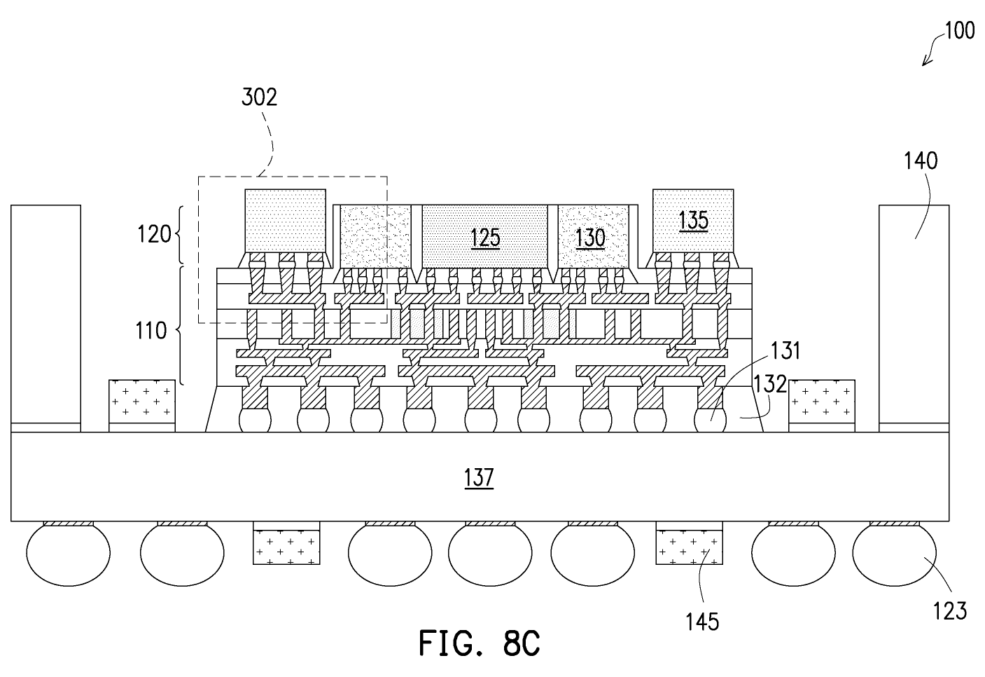

FIGS. 8A-8C illustrate a view of bonding a photonics chip 135, e.g., a compact photonics engine chip, to a redistribution layer (RDL) interposer substrate 110 by forming solder balls 165 through openings in the molding 117 from underfill/overmolding processes, in accordance with some embodiments.

FIG. 8A illustrates trimming the molding 117 to provide openings 118 to the contacts of the interconnect vias 115. Different from the embodiment depicted in FIG. 7A, a portion of the molding 117 remains after forming the openings 118 to the contacts of the interconnect vias 115. The remaining portion of the molding 117 remains within the final device structure and contributes to the total height of the upper surface of the photonics chip 135, e.g., compact photonics engine chip, once bonded to the front side redistribution layer (FSRDL) 112, being greater than the height of an upper surface of the package component 125, e.g., System-on-Chip (SoC) and/or System-on-Integrated Circuit (SoIC) chips, and/or above the upper surface of the memory components 130, e.g., high bandwidth memory (HBM) module.

In some embodiments, the molding 117 may be patterned and etched to provide openings 118 through the molding 117 that expose the upper surfaces of the interconnect vias 115. In some embodiments, an etch mask, such as a photoresist mask, may be formed exposing the portions of the molding 117 that is to be etched to form openings 118 to the upper surfaces of the interconnect vias 115. In some embodiments, the etch mask protects the portions of the molding 117 that will remain and be present between the photonics chip 135, e.g., compact photonics engine chip. In some embodiments, the etch mask also protects the other portions of the device so that they are not damaged by the etch process for removing the molding 117. In some embodiments, a photoresist mask may be formed by depositing a photoresist material layer, followed by patterning and development of the mask to provide the openings through which the etchant can remove the portions of the molding 117 to form openings 118 through the molding 117 to the interconnect vias 115 that the photonics chip 135, e.g., compact photonics engine chip, is to be bonded to. The photoresist material layer may be patterned using photolithography. The etch process for forming the openings 118 through the molding 117 may be an anisotropic etch process. For example, the anisotropic etch process for forming the openings 118 through the molding 117 may include reactive ion etching (RIE). In some embodiments, the etch process for forming the openings 118 through the molding 117 may remove the material of the molding 117 selectively to the insulating material of the front side redistribution layer (FSRDL) 112, as well as being selective to the interconnect vias 115. In some embodiments, if insulating material of the front side redistribution layer (FSRDL) 112 is present over the interconnect vias 115 it may also be removed using an etching process.

In some embodiments, prior to solder bonding the photonics chip 135, e.g., compact photonics engine chip, additional conductive material may be deposited in the openings 118, which can raise the height of the interconnect vias 115. The conductive material may include copper. In some other embodiments, the conductive material may include aluminum. In some other embodiments, the conductive material may be deposited using plating and/or physical vapor deposition (PVD) processes.

FIG. 8A also illustrates applying the solder ball 165, e.g., micro-ball, to the contacts 160 of the photonics chip 135, e.g., compact photonics engine chip. In some embodiments, the solder balls 165 may include micro-bumps, which can have a bump size of 25 microns or less. Further details on forming the solder balls 165, e.g., micro-bumps, have been provided above with reference to FIG. 7A.

After the application of solder to the contacts 160 for the photonics chip 135, e.g., compact photonics engine chip, the solder may then be contacted to the contacts on the contact pads of the interconnect vias 115 under elevated temperature and pressure to effectuate bonding, as depicted in FIG. 8B. FIG. 8B is an enlarged view of the window identified by reference number 302 in FIG. 8C. Following bonding, an underfill 161 may be applied. The underfill 161 may be a thermoset epoxy or polymer that's applied to solder balls 165 to protect them and strengthen solder joints. In some embodiments, the underfill 161 can be applied after the solder bump has gone through a reflow oven and can be dispensed using an automated syringe. The underfill 161 can flows underneath the photonics chip 135, e.g., compact photonics engine chip, using capillary action and can be heated to cure.

FIG. 8C is a side cross sectional view depicting the engagement, e.g., bonding, of the photonics chip 135, e.g., compact photonics engine chip, to the redistribution layer (RDL) interposer substrate 110. As illustrated in FIG. 8C, the upper surface of the compact photonics engine chip 135, e.g., COUPE chip, is above an upper surface of the top die components 120, e.g., an upper surface of the package component 125, e.g., System-on-Chip (SoC) and/or System-on-Integrated Circuit (SoIC) chips, and/or above the upper surface of the memory components 130, e.g., high bandwidth memory (HBM) module. However, the upper surface of the package component 12, e.g., the upper surface of the photonics chip 135, e.g., compact photonics engine chip, is coplanar with an upper surface of the ring structure 140. The increased height of the photonics chip 135 results from a remaining portion of the molding 117 being present between the photonics chip 135, e.g., compact photonics engine chip, and the redistribution layer (RDL) interposer substrate 110. By increasing the height of the upper surface of the photonics chip 135, e.g., compact photonic engine chip, to be equal to the height of the ring structure 140 the methods and structures provide a more accessible location for mounting a fiber array unit (FAU) to the photonics chip 135, e.g., compact photonic engine chip. The height of the photonics chip 135 may be adjusted independently from the height of the upper surface of the top die components 120.

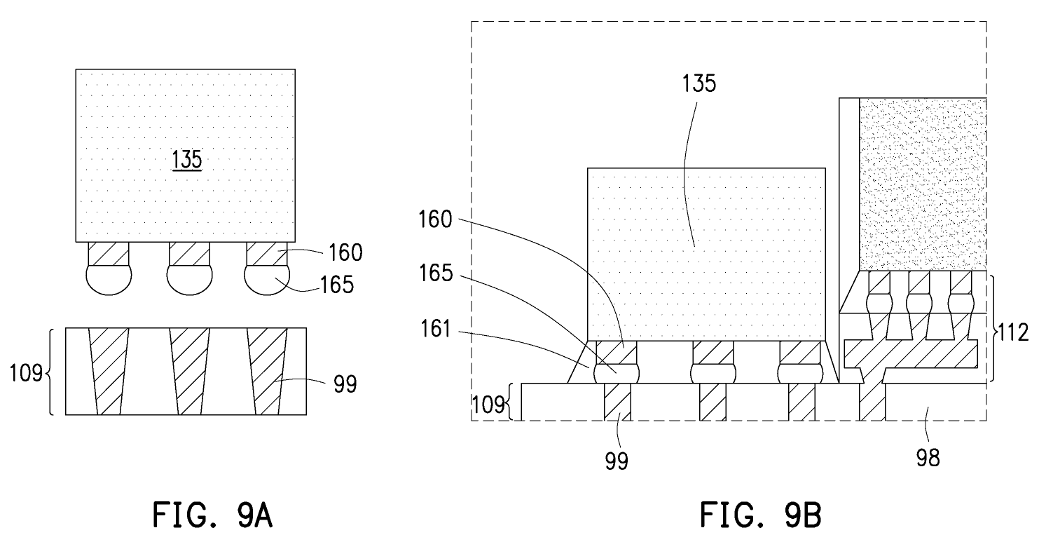

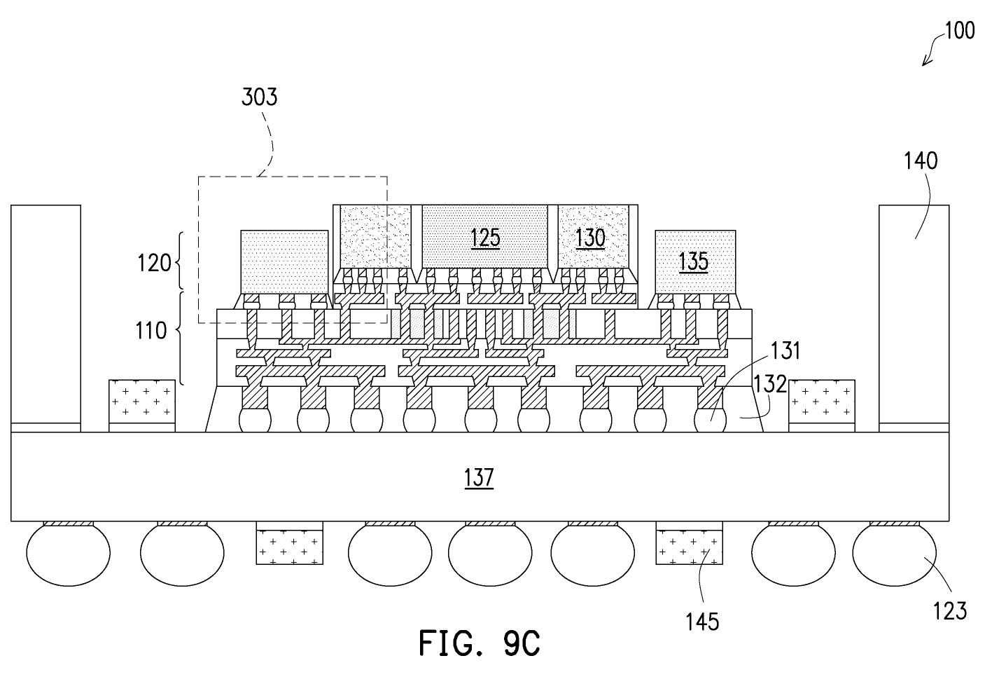

FIGS. 9A-9C illustrate views of some embodiments of bonding the photonics chip 135, e.g., compact photonic engine chip, to a redistribution layer (RDL) interposer substate 110 (as depicted in FIG. 9C) by bonding the photonics chip 135 to a through insulator via (TIV) 99 (which is also referred to as metal lines/interconnects) in the local silicon interconnect (LSI) layer 109.

FIG. 9A illustrates applying solder balls 165, e.g., micro-ball, to the contacts 160 of a photonics chip 135, e.g., compact photonic engine chip, before the photonics chip 135 is bonded to a through insulator via (TIV) 99 that is present in the local silicon interconnect (LSI) layer 109. Similar to the embodiments described above with reference to FIGS. 7A-7C, portions of the molding 117 are first entirely removed to expose the underlying portion of the front side redistribution layer (FSRDL) 112 adjacent to the top die components 120. After removing the molding 117, the exposed portion of the front side redistribution layer (FSRDL) 112 is removed to expose contact surfaces for a through insulator via (TIV) 99 within the local silicon interconnect (LSI) layer 109.

For example, the portions of the molding 117 and the front side redistribution layer (FSRDL) 112 that are overlying the through insulator vias (TIVs) 99 that the photonics chip 135 is to be bonded to may be removed using an etch process. In some embodiments, an etch mask, such as a photoresist mask, may be formed exposing the portions of the device including the portions of the molding 117 and the front side redistribution layer (FSRDL) 112 that are to be removed. In some embodiments, the photoresist mask may also protect the other portions of the device in which the etch process is not needed so that they are not damaged by the etch process for removing the molding 117 and the front side redistribution layer (FSRDL) 112. In some embodiments, a photoresist mask may be formed by blanket depositing a photoresist material layer, followed by patterning and development of the mask to provide the openings through which the etchant can remove the portions of the molding 117 and the front side redistribution layer (FSRDL) 112 that are overlying the through insulator vias (TIVs) 170 that the photonics chip 135, e.g., compact photonic engine chip, is to be bonded to. The photoresist material layer may be patterned using photolithography.

The etch process for removing the exposed portions of the molding 117 and the exposed portions of the front side redistribution layer (FSRDL) 112 may be an anisotropic etch process. For example, the anisotropic etch process for removing the molding 117 and the front side redistribution layer (FSRDL) 112 may include reactive ion etching (RIE). In some embodiments, the etch process for removing the molding 117 may remove the material of the molding 117 selectively to the insulating material of the front side redistribution layer (FSRDL) 112. In some embodiments, the etch process for removing the front side redistribution layer (FSRDL) 112 may be selective to the through insulator vias (TIVs) 99, as well as being selective to the insulating layer 98 of the local silicon interconnect (LSI) layer 109.

FIG. 9A also illustrates applying the solder ball 165, e.g., micro-ball, to the contacts 160 of the photonics chip 135, e.g., compact photonic engine chip. Further details on forming the solder balls 165, e.g., micro-bumps, have been provided above with reference to FIG. 7A.

After the application of solder to the contacts 160 for the photonics chip 135, e.g., compact photonic engine chip, the solder may then be contacted to the contacts of the through insulator vias (TIVs) 99 under elevated temperature and pressure to effectuate bonding, as depicted in FIG. 9B. FIG. 9B is an enlarged view of the window identified by reference number 303 in FIG. 9C. Following bonding, an underfill 161 may be applied. The underfill 161 may be a thermoset epoxy or polymer that's applied to solder balls 165 to protect them and strengthen solder joints. In some embodiments, the underfill 161 can be applied after the solder bump has gone through a reflow oven and can be dispensed using an automated syringe. The underfill 161 can flows underneath the photonics chip 135, e.g., compact photonic engine chip, using capillary action and can be heated to cure.

FIG. 9C is a side cross sectional view depicting the engagement, e.g., bonding, of the photonics chip 135, e.g., compact photonic engine chip, to the through insulator vias (TIVs) 99 of the local silicon interconnect (LSI) layer 109 including the local silicon interconnect (LSI) chips 111. As illustrated in FIG. 9C, the upper surface of the photonics chip 135, e.g., compact photonics engine chip, has a height that is lower than an upper surface of the top die components 120, e.g., has a height that is lower than an upper surface of the package component 125, e.g., System-on-Chip (SoC) and/or System-on-Integrated Circuit (SoIC) chips, and/or has a height that is lower than an upper surface of the memory components 130, e.g., high bandwidth memory (HBM) module. However, the upper surface of the photonics chip 135, e.g., compact photonics engine chip, is coplanar with an upper surface of the ring structure 140. FIGS. 9A-9C illustrate another embodiment in which the height of the photonics chip 135 may be adjusted independently from the height of the upper surface of the top die components 120. In this example, the height of the top die components 120 is greater than the height of the ring structure 140. To decrease the height of the photonics chip 135, the molding 117 and portions of the front side distribution layer (FSRDL) 112 are removed from the mounting point for the photonics chip 135. By decreasing the height of the upper surface of the photonics chip, e.g., compact photonics engine chip, to be coplanar with the upper surfaces of the ring structure 140, the methods and structures provide a more accessible location for mounting a fiber array unit (FAU) to the photonics chip 135, e.g., compact photonic engine chip.

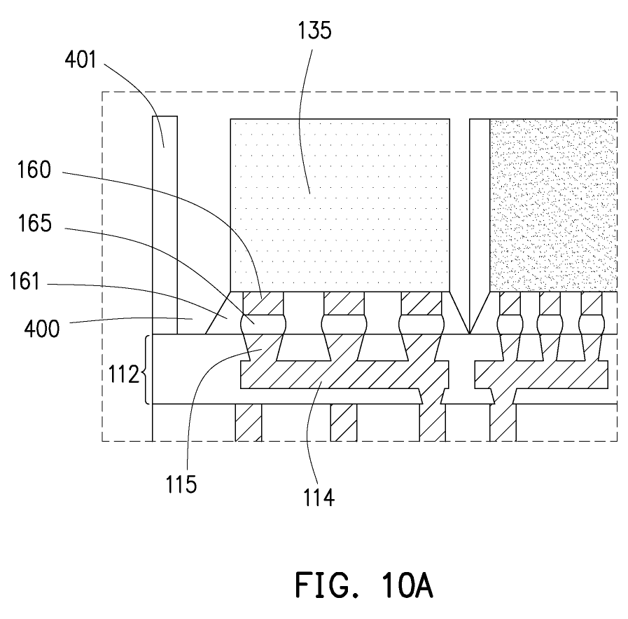

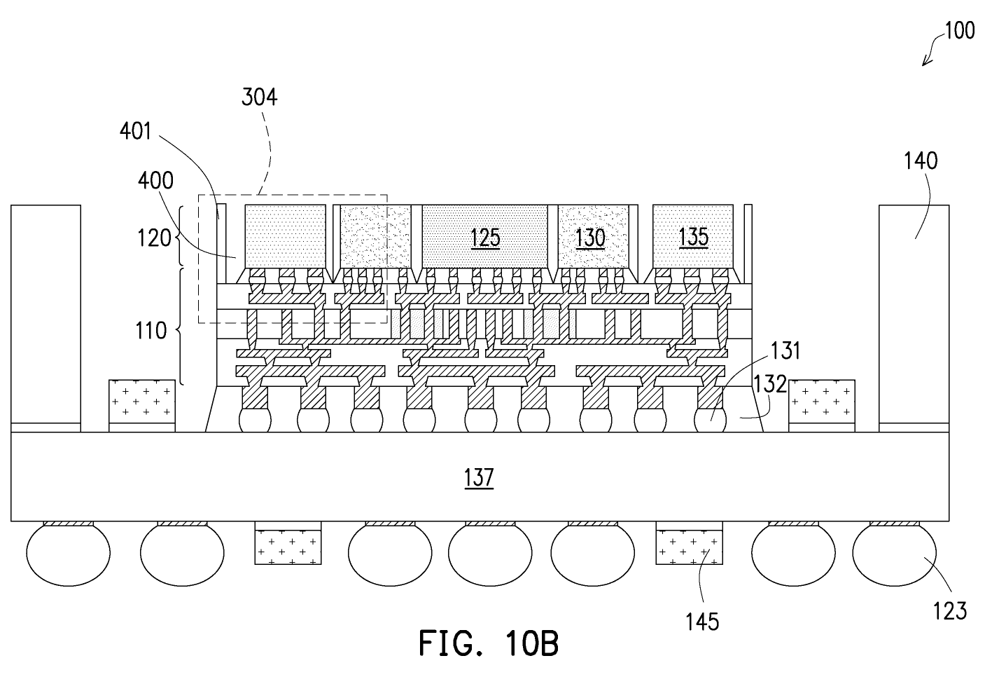

FIGS. 10A-12B illustrate some embodiments, in which the molding 117 may be trimmed to provide a hollow structure in which a remaining portion of the molding 117 can provide a molding wall 401 as the die edge. The hollow structure surrounds the package components 125, the memory components 130, and the photonics chip 135, e.g., the compact photonics engine chip. In each of the embodiments depicted in FIGS. 10A-12C, the hollow structure may be formed from the molding 117 using the deposition, photolithography and/or etch processes used to remove the molding 117 for exposing interconnects, e.g., through insulator via (TIV) 99 and/or interconnect vias 115, for bonding to the photonics chip 135, e.g., compact photonics engine chip. Sawing may be used as an alternative for etching the molding 117. For example, the hollow structure may be formed using a photoresist mask protecting the portion of the molding 117 that provides the molding wall 401. The etch process for defining the geometry of the molding wall 401 of the hollow structure may be an anisotropic etch, such as reactive ion etching (RIE). The molding wall 401 may be separated from the sidewall of the photonics chip 135, e.g., compact photonics engine chip, by a void 400, e.g., space filled by air. In some embodiments, the molding wall 401 may be formed by the photolithography and etch processes used to expose the interconnects, e.g., through insulator via (TIV) 170 and/or interconnect vias 115.

FIGS. 10A-10B illustrate views of bonding a photonics chip 135, e.g., compact photonics engine chip, to a redistribution layer (RDL) interposer substrate 110 using solder bonding methods, in which the molding 117 has been etched to provide hollow trim, in accordance with some embodiments. The solder bonding method depicted in FIGS. 10A-10B is similar to the method that is described above with reference to FIGS. 7A-7D. For example, the method depicted in FIGS. 10A-10B includes removing a portion of molding 117 from an upper surface of a front side redistribution layer (FSRDL) 112 that is adjacent to the portion of the top die including the memory components 130. Removing the molding 117 exposes upper surface of interconnect vias 115. Further details for etching the molding 117 are provided above with reference to FIGS. 7A-7D in which the elements having the same reference numbers in FIGS. 9A and 9B may be described by the descriptions for these elements provided above with reference to FIGS. 7A-7D. However, etching the molding 117 for the embodiments consistent with FIGS. 10A-10B further include masking and etch processes configures for forming the hollow structure, e.g., the molding wall 401. Still referring to FIGS. 10A-10B, after etch processing to expose the interconnect vias 115, the photonics chip 135, e.g., compact photonic engine chip, may be bonded to the interconnect vias 115 using solder bonding techniques. For example, the photonics chip 135 may be bonded to the interconnect vias 115 using solder balls 165, and an underfill 161 may also be applied.

FIG. 10A is an enlarged view of the window identified by reference number 304 in FIG. 10B. As illustrated in FIG. 10B, the upper surface of the photonics chip 135, e.g., compact photonic engine chip, is coplanar with an upper surface of the top die components 120, e.g., an upper surface of the package component 125, e.g., System-on-Chip (SoC) and/or System-on-Integrated Circuit (SoIC) chips, and/or is coplanar with the upper surface of the memory components 130, e.g., high bandwidth memory (HBM) module. As illustrated in FIG. 10B, the upper surface of the photonics chip 135, e.g., compact photonics engine chip, is coplanar with an upper surface of the ring structure 140.

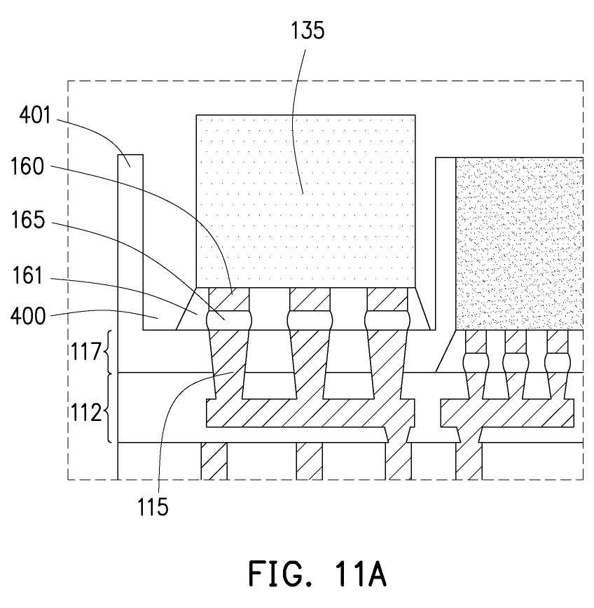

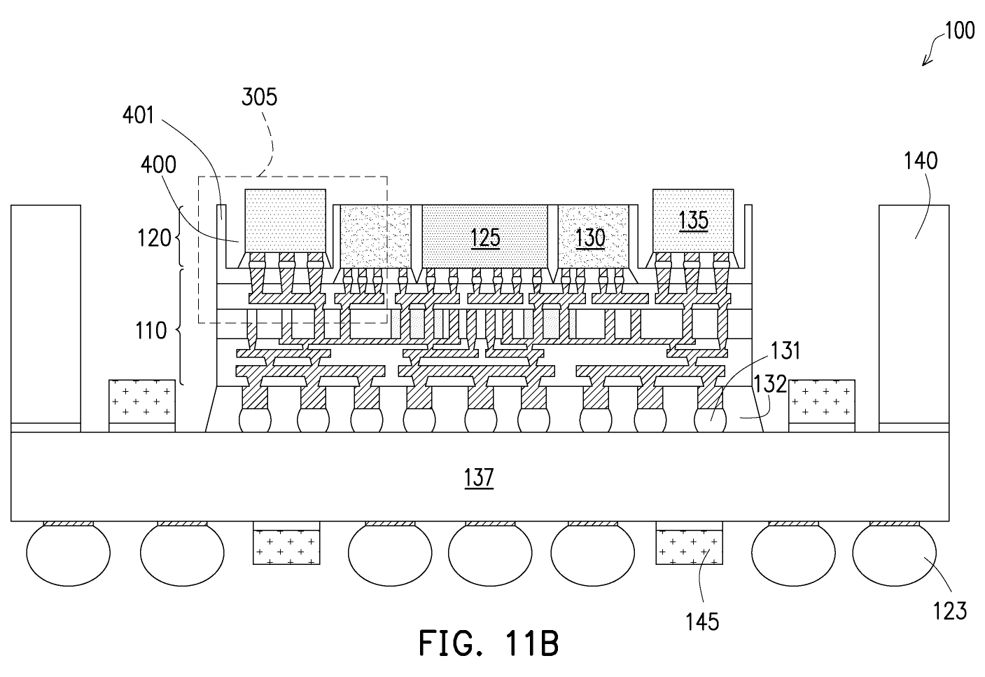

FIGS. 11A-11B illustrate view of bonding a photonics chip 135, e.g., a compact photonics engine chip, to a redistribution layer (RDL) interposer substrate 110 by forming solder balls 165 through openings in the molding from underfill/overmolding processes, in which the molding 117 has been etched to provide hollow trim, in accordance with some embodiments. The solder bonding method depicted in FIGS. 11A-11B is similar to the method that is described above with reference to FIGS. 8A-8C. For example, the method depicted in FIGS. 11A-11B includes forming openings in a portion of molding 117 that is adjacent to the portion of the top die including the memory components 130. Forming openings in the molding 117 exposes an upper surface of interconnect vias 115. Further details for etching the molding 117 are provided above with reference to FIGS. 8A-8C, in which the elements having the same reference numbers in FIGS. 11A and 11B may be described by the descriptions for these elements provided above with reference to FIGS. 8A-8C. However, etching the molding 117 for the embodiments consistent with FIGS. 11A-11B further include masking and etch processes configures for forming the hollow structure, e.g., the molding wall 401. Still referring to FIGS. 11A-11B, after etch processing to expose the interconnect vias 115, the photonics chip 135, e.g., compact photonics engine chip, may be bonded to the interconnect vias 115 using solder bonding techniques. For example, the photonics chip 135 may be bonded to the interconnect vias 115 using solder balls 165, and an underfill 161 may also be applied.

FIG. 11A is an enlarged view of the window identified by reference number 305 in FIG. 11B. As illustrated in FIG. 11B, the upper surface of the photonics chip 135, e.g., compact photonics engine chip, is above the upper surface of the top die components 120, e.g., is above an upper surface of the package component 125, e.g., System-on-Chip (SoC) and/or System-on-Integrated Circuit (SoIC) chips, and/or is above the upper surface of the memory components 130, e.g., high bandwidth memory (HBM) module. As illustrated in FIG. 11B, the upper surface of the photonics chip 135, e.g., compact photonics engine chip, is coplanar with an upper surface of the ring structure 140.

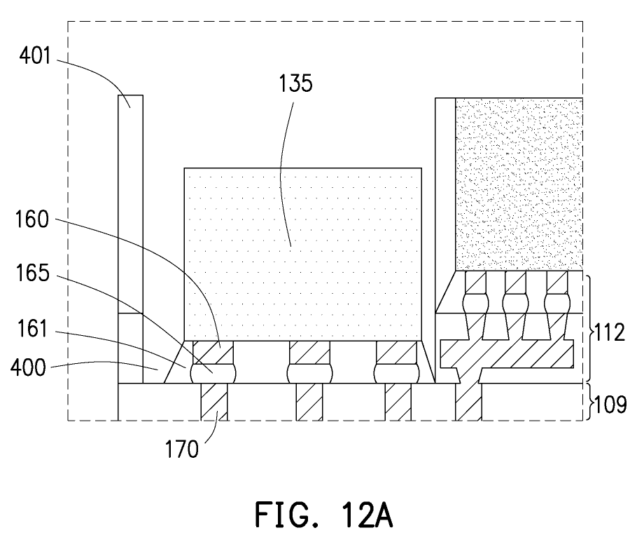

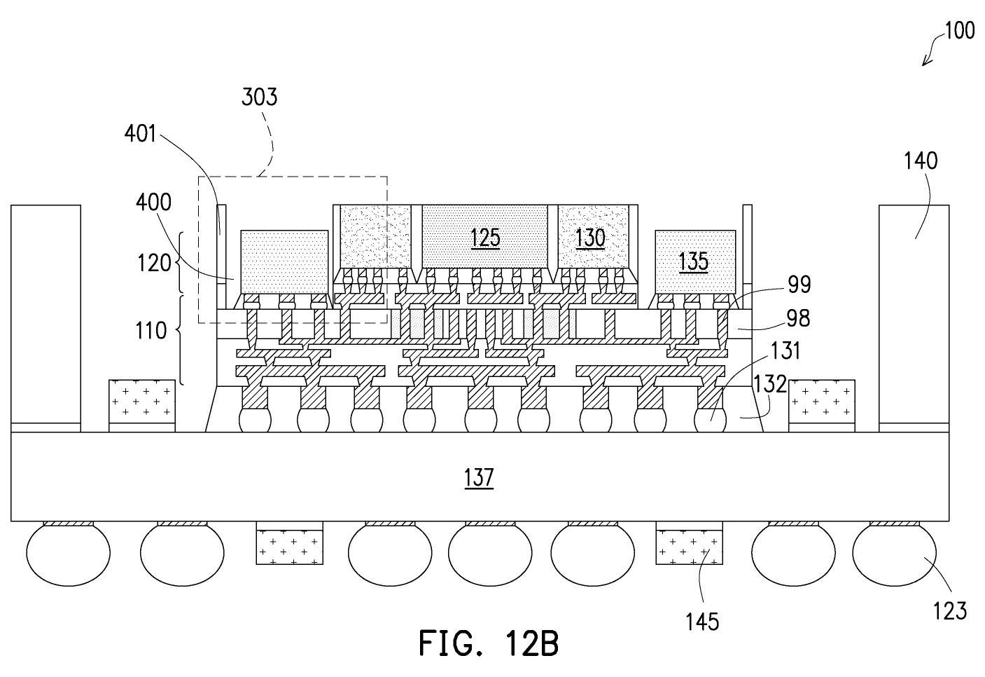

FIGS. 12A-12B illustrate view of bonding a photonics chip 135, e.g., a compact photonics engine chip, to a redistribution layer (RDL) interposer substrate 110 by forming solder balls 165 on a through insulator via (TIV) 170, in which the molding 117 has been etched to provide hollow trim, in accordance with some embodiments.

The solder bonding method depicted in FIGS. 12A-12B is similar to the method that is described above with reference to FIGS. 9A-9C. For example, the method depicted in FIGS. 12A-12B includes removing a portion of molding 117 and the front side redistribution layer (FSRDL) 112 that is adjacent to the portion of the top die including the memory components 130. Removing the molding 117 and the portion of the front side redistribution layer (FSRDL) 112 exposes an upper surface of through insulator vias (TIVs) 99. Further details for etching the molding 117 and the front side redistribution layer (FSRDL) 112 are provided above with reference to FIGS. 9A-9C, in which the elements having the same reference numbers in FIGS. 12 and 12 may be described by the descriptions for these elements provided above with reference to FIGS. 9A-9C. However, etching the molding 117 for the embodiments consistent with FIGS. 12A-12B further include masking and etch processes configures for forming the hollow structure, e.g., the molding wall 401. Still referring to FIGS. 12A-12B, after etch processing to expose the through insulator via (TIV) 170, the photonics chip 135, e.g., compact photonics engine chip, may be bonded to the through insulator via (TIV) 99 using solder bonding techniques. For example, the photonics chip 135 may be bonded to the through insulator via (TIV) 99 using solder balls 165, and an underfill 161 may also be applied.

FIG. 12A is an enlarged view of the window identified by reference number 306 in FIG. 12B. As illustrated in FIG. 12B, the upper surface of the photonics chip 135, e.g., compact photonics engine chip, is below the upper surface of the top die components 120, e.g., is below an upper surface of the package component 125, e.g., System-on-Chip (SoC) and/or System-on-Integrated Circuit (SoIC) chips, and/or is below the upper surface of the memory components 130, e.g., high bandwidth memory (HBM) module. As illustrated in FIG. 12B, the upper surface of the photonics chip 135, e.g., compact photonics engine chip, is coplanar with an upper surface of the ring structure 140.

In some embodiments, by bonding the photonics chip 135, e.g., compact photonics engine chip, to the upper surface of the redistribution layer (RDL) interposer substrate 110, the electrical pathway between the photonics chip 135, e.g., compact photonics engine chip, and the package components 125, e.g., System-on-Chip (SoC) and/or System-on-Integrated Circuit (SoIC) chips, are minimized, which can increase device performance. Additionally, mounting the photonics chip 135, e.g., compact photonics engine chip, to the upper surface of the redistribution layer (RDL) interposer substrate 110, as opposed to other locations, such as mounting to the substrate 137, can also advantageously reduce risk to the photonics chip 135, e.g., compact photonics engine chip, which could result from warpage. Further, by positioning the photonics chip 135, e.g., compact photonics engine chip, on the upper surface of the redistribution layer (RDL) interposer substrate 110, the methods and structures described herein allow for adjustability of the height of the upper surface of the photonics chip 135 so that it may be approximately equal to the height of the ring structure 140, which can aid in the attachment of a fiber array unit (FAU) to the photonics chip 135. Additionally, by mounting the photonics chip 135, e.g., compact photonics engine chip, to the upper surface of the redistribution layer (RDL) interposer substrate 110, the methods and structures described herein can allow for the package to more easily adopt local silicon interconnects (LSI), surface mount device (SMD) chips, ring structures (oscillator ring structures), lidded ring structures, and combinations thereof.

In one embodiment, a method comprising: bonding at least one of packaging components and memory components to an upper surface of a redistribution layer interposer substrate; bonding the redistribution layer interposer substrate onto a package substrate; removing molding from an upper surface of the redistribution layer interposer substrate to expose interconnect structures to the redistribution layer interposer substrate; and bonding a photonics chip to the upper surface of the redistribution layer interposer substrate. In an embodiment, the packaging components comprise a system on chip (SoC) component. In an embodiment, the packaging components comprise a system on integrated circuit component (SoIC). In an embodiment, a ring structure is present on the upper surface of the redistribution layer interposer substrate, the ring structure having an upper surface coplanar with an upper surface of the photonics chip. In an embodiment, an upper surface of the photonics chip is above an upper surface of the at least one of the packaging components and the memory components. In an embodiment, an upper surface of the photonics chip is coplanar with an upper surface of the at least one of the packaging components and the memory components. In an embodiment, an upper surface of the photonics chip is below an upper surface of the at least one of the packaging components and the memory components. In an embodiment, the method further includes removing the molding to expose the interconnector structures comprises exposing interconnect vias in the redistribution layer interposer substrate. In an embodiment, removing the molding comprises etching openings in the molding to expose interconnect pillars in the redistribution layer interposer substrate. In an embodiment, the redistribution layer interposer substrate comprises a local silicon interconnect layer including through insulator vias, a front side redistribution layer on a first side of local silicon interconnect layer, and a backside redistribution layer on a second side of the local silicon interconnect layer. In an embodiment, bonding the photonics chip to the upper surface of the redistribution layer interposer substrate comprises removing the molding and a portion of the front side redistribution layer to expose the through insulator vias (TIV). In an embodiment, the removing of the molding from the upper surface of the redistribution layer interposer substrate comprises forming a molding wall for a hollow structure surrounding the packaging components, the memory components, and the photonics chip.

In another embodiment, a structure comprising: a redistribution layer interposer substrate bonded onto a package substrate; die components bonded to an upper surface of the redistribution layer interposer substrate; and a photonics chip bonded to the upper surface of the redistribution layer interposer substrate, wherein a portion of a molding layer is between the photonics chip and the redistribution layer interposer substrate. In an embodiment, the die components comprise packaging components. In an embodiment, the die components comprise memory components. In an embodiment, a ring structure is present on the upper surface of the redistribution layer interposer substrate, the ring structure having an upper surface coplanar with an upper surface of the photonics chip. In an embodiment, an upper surface of the photonics chip is above an upper surface of the at least one of the die components. In an embodiment, an upper surface of the photonics chip is coplanar with an upper surface of the at least one of the die components. In an embodiment, an upper surface of the photonics chip is below an upper surface of the at least one of the die components.

In yet another embodiment, a structure comprising a redistribution layer interposer substrate bonded onto a package substrate; top die components bonded to an upper surface of the redistribution layer interposer substrate; a photonics chip bonded to the upper surface of the redistribution layer interposer substrate; and a molding wall defining a hollow structure around the top die components and the photonics chip.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
an interposer;
a first semiconductor die bonded to a first side of the interposer;
an encapsulant surrounding the first semiconductor die; and
an optical chip bonded to the first side of the interposer, wherein the optical chip extends along a sidewall of the first semiconductor die, and wherein a first outer sidewall of the encapsulant is disposed between the optical chip and the first semiconductor die.

2. The package of claim 1, wherein the interposer comprises a first redistribution structure, and wherein the first redistribution structure comprises:
a first insulating layer; and
first conductive features in the first insulating layer, wherein the first semiconductor die is bonded to the first conductive features.

3. The package of claim 2, wherein the first redistribution structure further comprises: second conductive features in the first insulating layer, wherein the optical chip is bonded to the second conductive features.

4. The package of claim 2, wherein the first redistribution structure further comprises:
second conductive features protruding from the first insulating layer, wherein the optical chip is bonded to the second conductive features.

5. The package of claim 4, wherein a portion of the encapsulant is disposed around upper portions of the second conductive features, and wherein the optical chip overlaps the portion of the encapsulant.

6. The package of claim 2, wherein the first redistribution structure further comprises:
second conductive features extending through an insulating material, wherein the first insulating layer is disposed between the insulating material and the first insulating layer, and wherein the optical chip is bonded to the second conductive features.

7. The package of claim 6, further comprising:
a second semiconductor die bonded to the first side of the interposer, wherein the encapsulant surrounds the second semiconductor die; and
an interconnect die in the insulating material, wherein the interconnect die electrically connects the first semiconductor die to the second semiconductor die.

8. The package of claim 1, wherein the optical chip is disposed in a cavity that extends through the encapsulant, wherein the cavity is disposed between the first outer sidewall and a second outer sidewall of the encapsulant.

9. The package of claim 1, wherein a top surface of the optical chip and a top surface of the first semiconductor die are disposed at different levels.

10. A package comprising:
an interposer comprising:
an interconnect die;
a first insulating material surrounding the interconnect die; and
a first redistribution structure and a second redistribution structure on opposing sides of the first insulating material, wherein the first redistribution structure comprises first conductive features in a first insulating layer;
a first semiconductor die and a second semiconductor die bonded to the first conductive features of the interposer, wherein the interconnect die electrically connects the first semiconductor die to the second semiconductor die;
a second insulating material surrounding the first semiconductor die and the second semiconductor die; and
an optical chip bonded to a same side of the interposer as the first semiconductor die, wherein the optical chip is spaced apart from a sidewall of the second insulating material by a gap.

11. The package of claim 10, wherein the optical chip is bonded to second conductive features in the first insulating layer.

12. The package of claim 11, wherein upper portions of the second conductive features extend above the first insulating layer and the first conductive features.

13. The package of claim 12, wherein the second insulating material surrounds the upper portions of the second conductive features.

14. The package of claim 10, wherein the optical chip is disposed in a cavity that extends at least partially through the second insulating material.

15. The package of claim 14, wherein the cavity further extends through the first insulating layer, and wherein the optical chip is bonded to a plurality of conductive features in the first insulating material.

16. The package of claim 14, wherein the cavity extends completely through the second insulating material in a cross-sectional view.

17. A package comprising:
an interposer over and bonded to a package substrate;
die components bonded to an upper side of the interposer;
a molding compound encapsulating the die components; and
a photonics chip bonded to the upper side of the interposer, wherein the photonics chip is disposed in a cavity in the molding compound.

18. The package of claim 17, wherein the cavity extends from a first sidewall of the molding compound to a second sidewall of the molding compound, and wherein the photonics chip is between the first sidewall and the second sidewall of the molding compound.

19. The package of claim 17, wherein the photonics chip extends above a top surface of the molding compound.

20. The package of claim 17, wherein the molding compound extends above a top surface of the photonics chip.
